(19) United States
(12) Patent Application Publication
(10) Pub. No.: US 2003/0222873 A1
(43) Pub. Date: Dec. 4, 2003

(54) Sequence display

(76) Inventor: Gilles Ritter, Ollon (CH)

Correspondence Address: FROMMER LAWRENCE & HAUG, 745 FIFTH AVENUE- 10TH FL., NEW YORK, NY, 10151, US

(21) Appl. No.: 10/436,788

(22) Filed: May 13, 2003

Related U.S. Application Data
(60) Provisional application No. 60/383,745, filed on May 28, 2002.

(51) Int. Cl. G01R 13/20

(52) U.S. Cl. 345/440

(57) ABSTRACT

An oscilloscope, comprising a display, a display controller for controlling information to be displayed on the display, and an acquisition system for acquiring a sequence of waveforms. Two or more of the sequentially acquired waveforms are displayed employing a small vertical shift and a small horizontal shift, thus resulting in a diagonal positioning of each waveform relative to each previously drawn waveform.

### CROSS REFERENCE TO RELATED APPLICATIONS

This application claims the benefit of U.S. Provisional Patent Application No. 60/383,745, filed May 28, 2002, the entire contents of which are incorporated herein by reference.

### BACKGROUND OF THE INVENTION

Oscilloscopes are used by individuals to view waveforms. These waveforms may be acquired at a particular location along a signal path in a piece of electronic equipment, as a background noise reading, or at any other location an electromagnetic signal is present. The oscilloscope typically will acquire a number of consecutive waveforms. The user may wish to compare the shape of these waveforms to determine whether the shape is changing over time, and whether one or more of the acquisitions shows an error or inconsistency, thus indicating an intermittent problem with the signal. However, traditionally the ability for a user to perform this type of comparison has been severely limited.

The initial problem comes from the way acquisition works in a scope. In accordance with a standard configuration, during each acquisition the oscilloscope is configured to acquire one waveform. After acquisition, software in the oscilloscope acts upon the acquired waveform data and displays the waveform on a display screen. However, there is a time period during display of the first acquired waveform when no data is being acquired. If an error were to occur during this time, it would not be reflected in the display. Thus, during the time the scope is displaying the first acquired waveform and is reconfiguring its acquisition system to acquire the next waveform, an error or other event that the user might want to view may occur in the measured signal. This event will not be captured by the acquisition system, and finally the user will therefore not be made aware of the event in the signal.

To minimize that problem, the acquisition system of the oscilloscope may be configured so that as soon as an acquisition of a first waveform has been completed, the acquisition system immediately begins acquisition of the next waveform. In accordance with such a configuration, instead of producing only one waveform at a time, a sequence of waveforms is produced. The time between each waveform of the sequence is minimized. Therefore, the chance of missing an event in the acquired signal that the user may wish to view is minimized.

Once such a sequence of waveforms has been acquired, the user may want to analyze the waveforms in the sequence. A special display mode is typically provided to allow the user to look at a number of waveform sequences at once. Such a conventional special display mode is show in FIG. 1. As is shown, each waveform 110 of a sequence of waveforms 105 is displayed side by side from left to right of the display 100. The display of each of these waveforms in this fashion, however, results in a reduction in the width available to display each waveform. Therefore the shape of the waveform is changed, and may make it more difficult to spot events in a waveform, or differences between waveforms. Increasing the number of waveforms in the sequence continues to substantially reduce the width of each waveform. They therefore quickly become too small to analyze. As is thus shown in FIG. 1, because of the reduced width available for each signal, it is difficult to determine any particular features of the signals.

### SUMMARY OF THE INVENTION

In order to overcome the problems associated with the traditional display modes, and so that a plurality of waveforms may be displayed without a corresponding reduction in the width of each of the waveforms, a plurality of different improved display modes have been developed in accordance with the invention.

An “Overlap” display is provided in which each waveform in the sequence is drawn overlaid on top of the previously drawn waveforms in the sequence. A “Waterfall” display is provided in which each waveform is drawn above the previously drawn waveform, thus vertically shifting each waveform relative to the previously drawn waveform. A “Perspective” display is provided in which each waveform is drawn after being shifted diagonally across the screen relative to the previously drawn waveform. A “Tile, mosaic” display is provided in which each waveform is drawn in a cell of a virtual grid dividing the full screen. Each cell of the virtual grid preferably has substantially the same ratio of dimensions as complete display, therefore not altering the overall perspective of any of the waveforms in the sequence. Each of these provided display modes allows the user to analyze different properties of the same measured signal in a manner not available with a conventional oscilloscope.

All of these improved display modes may also be employed in a normal acquisition mode (non-sequence) in addition to the sequential acquisition mode described above. In such a non-sequential acquisition mode, upon each acquisition, the newly acquired waveform is added to the current display at the next location according to the display mode. Such a procedure therefore displays the evolution of the signal through successive acquisitions. The history of the signal is preserved while up-to-date information is acquired.

Still other objects and advantages of the invention will in part be obvious and will in part be apparent from the specification and the drawings.

The invention accordingly comprises the several steps and the relation of one or more of such steps with respect to each of the others, and the apparatus embodying features of construction, combination(s) of elements and arrangement of parts that are adapted to effect such steps, all as exemplified in the following detailed disclosure, and the scope of the invention will be indicated in the claims.

### BRIEF DESCRIPTION OF THE DRAWINGS

For a more complete understanding of the invention, reference is made to the following description and accompanying drawings, in which:

FIG. 1 is a representation of a conventional display of a sequential acquisition of a series of waveforms in which each waveform is displayed side by side from left to right of the screen;

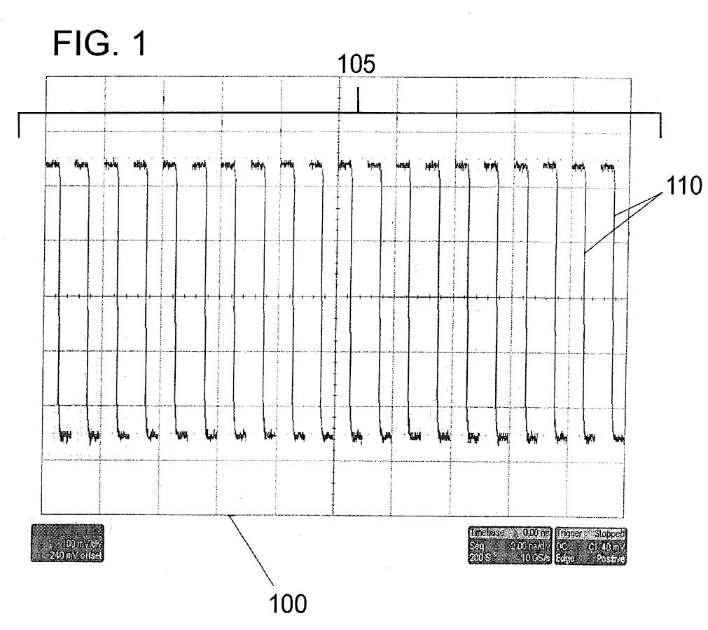

FIG. 2 is a representation of an overlap display in accordance with the invention in which each waveform is displayed full screen overlaid on top of the previously displayed waveforms;

FIG. 3 is a representation of a waterfall display in accordance with the invention in which each waveform is displayed full screen, shifted vertically relative to the previously drawn waveform;

FIG. 4 is a representation of a perspective display in accordance with the invention in which each waveform is displayed after being shifted diagonally across the screen (shifted horizontally and vertically) relative to the previously drawn waveform; and

FIG. 5 is a representation of a tiled, mosaic display in which each waveform is drawn in a cell of a virtual grid dividing the full screen.

### DETAILED DESCRIPTION OF THE PREFERRED EMBODIMENTS

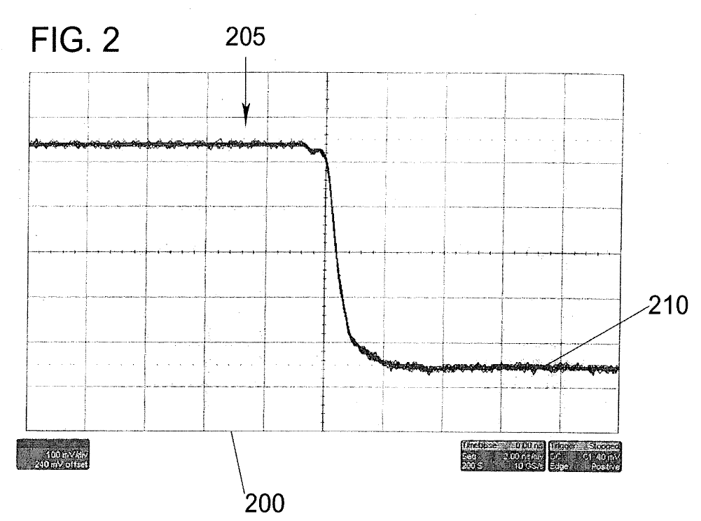

Referring first to FIG. 2 an improved display for an oscilloscope that is controlled by a display controller in accordance with a first embodiment of the invention is shown. In FIG. 2, a plurality of waveforms 210 comprising a sequence of waveforms 205 is shown on a display 200. The acquisition system of the oscilloscope is configured so that as soon as an acquisition of a first waveform has been completed, the acquisition system immediately begins acquisition of the next waveform. In accordance with such a configuration, instead of producing only one waveform at a time, a sequence of waveforms is produced. The time between each waveform of the sequence is minimized. Therefore, the chance of missing an event in the acquired signal that the user may wish to view is minimized. In accordance with this embodiment of the invention, the acquired sequence of waveforms is displayed in an “overlap” display mode in which all of the sequentially or consecutively acquired waveforms are overlaid on top of each other using the full screen. This display is useful to analyze any variation between waveforms in a signal. As can be seen in FIG. 2, noise associated with a particular waveform causes the waveforms to not precisely overlap in all portions of the signal. If a large deviation were present, it would be visible as a single waveform producing a line on the display that was obviously set apart from the remainder of the overlapping waveforms. Thus, it is easy to see if one waveform has a problem and deviates from the other waveforms.

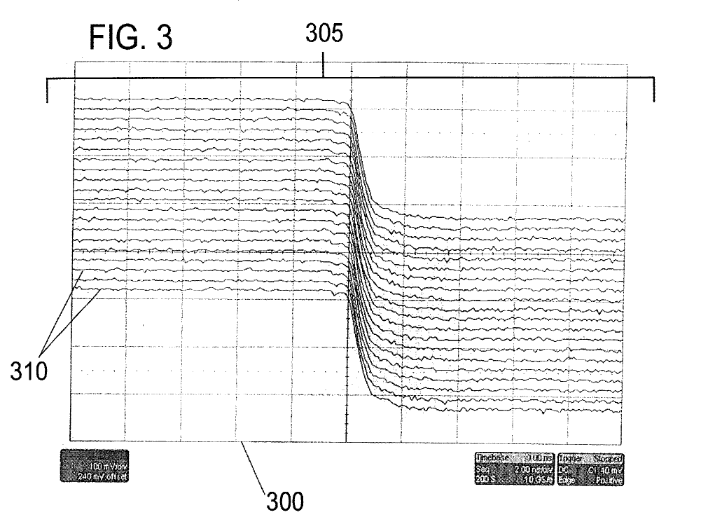

Referring next to FIG. 3, an improved display in accordance with a second embodiment of the invention is shown. In FIG. 3, a plurality of waveforms 310 comprising a sequence of waveforms 305 is shown on a display 300. In accordance with this “waterfall” display all of the sequentially or consecutively acquired waveforms are displayed employing a small vertical shift. The full width of the screen is used for each waveform, while the height is reduced in order to fit all waveforms of the sequence into the screen. Therefore, any absolute and relative measurements along the x-axis of the display are valid for any waveform, but only relative features (bump or excursion) between adjacent waveforms can be measured using the y-axis. This display mode is useful to identify if one waveform is not correctly aligned in time horizontally (jitter) with the other waveforms. It also allows for easy identification of which waveform may have an aberration or differ from the other waveforms.

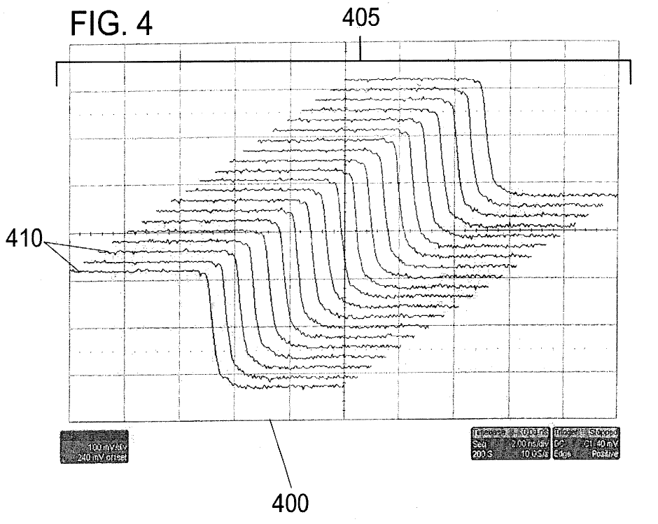

Referring next to FIG. 4, an improved display in accordance with a third embodiment of the invention is shown. In FIG. 4, a plurality of waveforms 410 comprising a sequence of waveforms 405 is shown on a display 400. In accordance with this “perspective” display all of the sequentially or consecutively acquired waveforms are displayed employing a small vertical shift and a small horizontal shift, thus resulting in a diagonal positioning of each waveform relative to previously drawn waveforms. The width and height of each waveform are reduced slightly in order to fit all waveforms into the screen, but in reducing the size of the waveforms a similar percentage in each direction, the relative scales of each individual waveform is preserved. This displaying of the multiple waveforms creates an effect of perspective that allows the user to quickly analyze the shape of the waveforms.

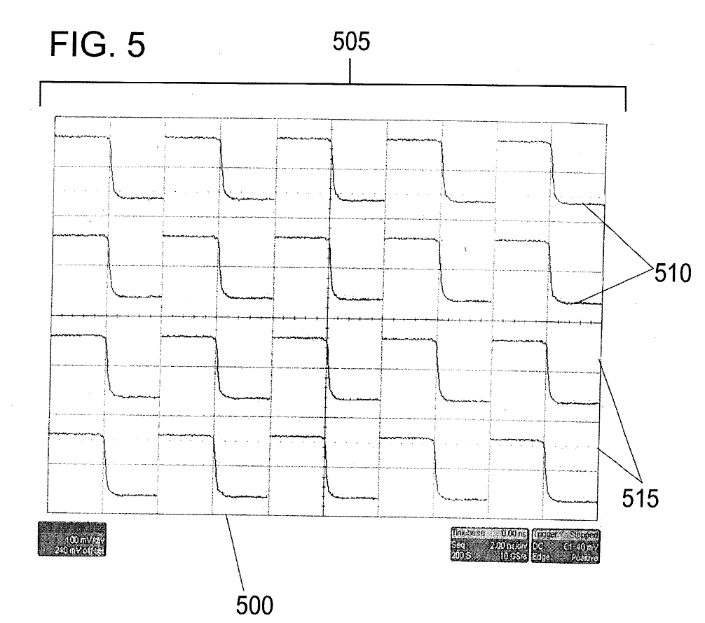

Referring next to FIG. 5, an improved display in accordance with a fourth embodiment of the invention is shown. In FIG. 5, a plurality of waveforms 510 comprising a sequence of waveforms 505 is shown on a display 500. In accordance with this “tile, mosaic” display all of the sequentially or consecutively acquired waveforms are displayed in accordance with a tiled pattern, each waveform being displayed in its own cell 515. The full screen 500 is divided into a grid (multiple lines and column) and each waveform 505 is displayed in one cell 515 of the grid. The width and height of each waveform is adapted to fit in a cell of the grid, but allows for each waveform to be displayed in a perspective similar to that of the original display. This display mode has the advantage of conserving the ratio between width and height of each waveforms and allow the user a quick look at a greater number of waveform segments while not altering the look or displayed shape of each of the waveforms. Additionally, the waveforms are not drawn too small to be useful for analysis.

In addition to providing a number of innovative viewing schemes for the display of acquired waveforms, the apparatus in accordance with the invention also provides additional controls for use by a user in order to exploit these additional viewing schemes. In accordance with the conventional system the user could either display all waveforms of a sequence at once, or display one waveform within the sequence at a time. In accordance with the invention, the user can select the number of waveforms to be viewed on the display simultaneously, from one to the number of acquired waveforms. Then, to select which group of waveforms within the entire sequence is displayed (i.e. which is to be the first waveform to be displayed), a second control specifies the first displayed waveform within the entire sequence. These controls in accordance with the invention allow the user to more quickly and easily view and analyze, for example 20 by 20 waveform at a time through an entire sequence of waveforms instead of having to look at each waveform one by one. By selecting a desired number of waveforms to be displayed, an appropriate balance can be drawn between the size of each waveform and the speed of moving through a sequence of waveforms.

It will thus be seen that the objects set forth above, among those made apparent from the preceding description, are efficiently attained and, because certain changes may be made in carrying out the above method and in the construction(s) set forth without departing from the spirit and scope of the invention, it is intended that all matter contained in the above description and shown in the accompanying drawings shall be interpreted as illustrative and not in a limiting sense.

It is also to be understood that the following claims are intended to cover all of the generic and specific features of the invention herein described and all statements of the scope of the invention which, as a matter of language, might be said to fall therebetween.

What is claimed:

1. An oscilloscope, comprising:
a display;
a display controller for controlling information to be displayed on said display; and
an acquisition system for acquiring a sequence of waveforms;
wherein two or more of the sequentially acquired waveforms are overlaid on top of each other using the full screen.

2. The oscilloscope of claim 1, wherein noise associated with a particular waveform causes the waveforms to not precisely overlap with the other sequentially acquired waveforms.

3. An oscilloscope, comprising:
a display;
a display controller for controlling information to be displayed on said display; and
an acquisition system for acquiring a sequence of waveforms;
wherein two or more of the sequentially acquired waveforms are displayed employing a small vertical shift.

4. The oscilloscope of claim 3, wherein the full width of the screen is used for each waveform, while the height is reduced in order to fit all waveforms of the sequence into the screen.

5. The oscilloscope of claim 4, wherein an absolute scale employed along an x-axis of the display is applicable for all waveforms, but any relative positioning between adjacent waveforms is measured using the y-axis scale.

6. The oscilloscope of claim 3, wherein a user is able to identify if one waveform is not correctly aligned in time horizontally, as a result of jitter, with the other acquired waveforms.

7. An oscilloscope, comprising:
a display;
a display controller for controlling information to be displayed on said display; and
an acquisition system for acquiring a sequence of waveforms;
wherein two or more of the sequentially acquired waveforms are displayed employing a small vertical shift and a small horizontal shift, thus resulting in a diagonal positioning of each waveform relative to each previously drawn waveform.

8. The oscilloscope of claim 7, wherein the width and height of each waveform are reduced slightly in order to fit all waveforms into the display.

9. The oscilloscope of claim 8, wherein the size of each of the waveforms is reduced a similar percentage in each direction so that the original perspective of each individual waveform is preserved.

10. The oscilloscope of claim 7, wherein a user is quickly able to analyze the shape of the waveforms

11. An oscilloscope, comprising:
a display;
a display controller for controlling information to be displayed on said display; and
an acquisition system for acquiring a sequence of waveforms;
wherein two or more of the sequentially acquired waveforms are displayed in accordance with a tiled pattern, each waveform being displayed in its own cell.

12. The oscilloscope of claim 11, wherein the display is divided into a grid including multiple lines and columns and each waveform is displayed in one cell of the grid.

13. The oscilloscope of claim 12, wherein the width and height of each waveform is adapted to fit in a cell of the grid, but allows for each waveform to be displayed in a perspective similar to that of the original display.

14. The oscilloscope of claim 13, wherein the ratio between width and height of each waveforms depicted in the grid and in the original sample is preserved.

15. The oscilloscope of claim 11, wherein a user is able to look at a greater number of waveform segments while not altering the look or displayed shape of each of the waveforms.

16. The oscilloscope of claim 11, wherein a use selects a number of waveforms to be display on said display, and the number of selected waveforms determines a size of each of the tiles.
